(19) United States
(12) Patent Application Publication
(10) Pub. No.: US 2022/0375802 A1
(43) Pub. Date: Nov. 24, 2022

(54) TEST STRUCTURE OF INTEGRATED CIRCUIT

(71) Applicant: CHANGXIN MEMORY TECHNOLOGIES, INC., Hefei City (CN)

(72) Inventor: Qian Xu, Hefei City (CN)

(21) Appl. No.: 17/659,052

(22) Filed: Apr. 13, 2022

(30) Foreign Application Priority Data
May 19, 2021 (CN) 202110548445.3

(51) Int. Cl. H01L 21/66; H01L 29/735

(52) U.S. Cl. CPC H01L 22/30; H01L 29/735

(57) ABSTRACT

Embodiments of the present disclosure relate to the technical field of integrated circuits, and specifically to a test structure of an integrated circuit. The embodiments of the present disclosure are intended to solve the problem that the related art does not provide a test structure of an integrated circuit. In the test structure of an integrated circuit provided in the present disclosure, there is a first distance between a first N-type heavily doped region and a second N-type heavily doped region, and there is a second distance between the second N-type heavily doped region and a first P-type heavily doped region; electrical parameters of the integrated circuit corresponding to the test structure are tested by adjusting at least one of the first distance and the second distance.

### CROSS-REFERENCE TO RELATED APPLICATION

This application claims the priority of Chinese Patent Application No. 202110548445.3, submitted to the Chinese Intellectual Property Office on May 19, 2021, the disclosure of which is incorporated herein in its entirety by reference.

### TECHNICAL FIELD

Embodiments of the present disclosure relate to the technical field of integrated circuits, and in particular, to a test structure of an integrated circuit.

### BACKGROUND

A latch-up is a parasitic effect unique to a CMOS process, which can lead to a circuit failure and even chip burnout. In a CMOS integrated circuit, a parasitic NPN transistor is electrically unstable and is susceptible to a latch-up under the influence of static electricity or related voltage transients. When a latch-up occurs, the NPN transistor is in an amplified state, an emitter is forward-biased, and a collector is reverse-biased. While a semiconductor component forms a low-impedance path between a power supply voltage and ground, a positive feedback loop enables the circuit to maintain the low-impedance path, resulting in a high current and permanent damage to the chip.

In order to ensure the reliability of the chip, it is necessary to avoid the latch-up of the integrated circuit. Therefore, in a chip development stage, it is necessary to test various parasitic NPN transistor structures that may exist in the integrated circuit and extract corresponding rule parameters to design the integrated circuit, so as to avoid the latch-up.

### SUMMARY

According to a first aspect, an embodiment of the present disclosure provides a test structure of an integrated circuit, including:

a first N-type heavily doped region, a first P-type heavily doped region, and a second N-type heavily doped region located between the first N-type heavily doped region and the first P-type heavily doped region;

wherein the first N-type heavily doped region, the second N-type heavily doped region, and the first P-type heavily doped region are all located on a P-type substrate; there is a first distance between the first N-type heavily doped region and the second N-type heavily doped region, and there is a second distance between the second N-type heavily doped region and the first P-type heavily doped region; and

the test structure is configured to test electrical parameters of the integrated circuit corresponding to the test structure by adjusting at least one of the first distance and the second distance.

According to a second aspect, an embodiment of the present disclosure provides a test structure of an integrated circuit, including:

a first N-type heavily doped region, a first P-type heavily doped region, and a second N-type heavily doped region located between the first N-type heavily doped region and the first P-type heavily doped region;

wherein the first N-type heavily doped region is located in an N well, the second N-type heavily doped region and the first P-type heavily doped region are both located on a P-type substrate, and the N well is located on the P-type substrate;

there is a first distance between the first N-type heavily doped region and the second N-type heavily doped region, and there is a second distance between the second N-type heavily doped region and the first P-type heavily doped region; and

the test structure is configured to test electrical parameters of the integrated circuit corresponding to the test structure by adjusting at least one of the first distance and the second distance.

According to a third aspect, an embodiment of the present disclosure provides a test structure of an integrated circuit, including:

a first N-type heavily doped region, a first P-type heavily doped region, and a second N-type heavily doped region located between the first N-type heavily doped region and the first P-type heavily doped region;

wherein the first N-type heavily doped region is located in a deep N well, the second N-type heavily doped region and the first P-type heavily doped region are both located on a P-type substrate, the deep N well is located in an N well, and the N well is located on the P-type substrate;

there is a first distance between the first N-type heavily doped region and the second N-type heavily doped region, and there is a second distance between the second N-type heavily doped region and the first P-type heavily doped region; and

the test structure is configured to test electrical parameters of the integrated circuit corresponding to the test structure by adjusting at least one of the first distance and the second distance.

According to a fourth aspect, an embodiment of the present disclosure provides a test structure of an integrated circuit, including:

a first N-type heavily doped region, a first P-type heavily doped region, and a second N-type heavily doped region located between the first N-type heavily doped region and the first P-type heavily doped region;

wherein the second N-type heavily doped region is located in an N well, the first N-type heavily doped region and the first P-type heavily doped region are located on a P-type substrate, and the N well is located on the P-type substrate;

there is a first distance between the first N-type heavily doped region and the second N-type heavily doped region, and there is a second distance between the second N-type heavily doped region and the first P-type heavily doped region; and

the test structure is configured to test electrical parameters of the integrated circuit corresponding to the test structure by adjusting at least one of the first distance and the second distance.

According to a fifth aspect, an embodiment of the present disclosure provides a test structure of an integrated circuit, including:

a first N-type heavily doped region, a first P-type heavily doped region, and a second N-type heavily doped region located between the first N-type heavily doped region and the first P-type heavily doped region;

wherein the second N-type heavily doped region is located in a deep N well , the first N-type heavily doped region and the first P-type heavily doped region are both located on a P-type substrate, the deep N well is located in an N well, and the N well is located on the P-type substrate;

there is a first distance between the first N-type heavily doped region and the second N-type heavily doped region, and there is a second distance between the second N-type heavily doped region and the first P-type heavily doped region; and

the test structure is configured to test electrical parameters of the integrated circuit corresponding to the test structure by adjusting at least one of the first distance and the second distance.

According to a sixth aspect, an embodiment of the present disclosure provides a test structure of an integrated circuit, including:

a first N-type heavily doped region, a first P-type heavily doped region, and a second N-type heavily doped region located between the first N-type heavily doped region and the first P-type heavily doped region;

wherein the first N-type heavily doped region is located in a first N well, the second N-type heavily doped region is located in a second N well, and the first P-type heavily doped region, the first N well, and the second N well are all located on a P-type substrate;

there is a first distance between the first N-type heavily doped region and the second N-type heavily doped region, and there is a second distance between the second N-type heavily doped region and the first P-type heavily doped region; and

the test structure is configured to test electrical parameters of the integrated circuit corresponding to the test structure by adjusting at least one of the first distance and the second distance.

According to a seventh aspect, an embodiment of the present disclosure provides a test structure of an integrated circuit, including:

a first N-type heavily doped region, a first P-type heavily doped region, and a second N-type heavily doped region located between the first N-type heavily doped region and the first P-type heavily doped region;

wherein the first N-type heavily doped region is located in a first N well, the second N-type heavily doped region is located in a deep N well, the first P-type heavily doped region is located on a P-type substrate, the first N well is located on the P-type substrate, the deep N well is located in a second N well, and the second N well is located on the P-type substrate;

there is a first distance between the first N-type heavily doped region and the second N-type heavily doped region, and there is a second distance between the second N-type heavily doped region and the first P-type heavily doped region; and

the test structure is configured to test electrical parameters of the integrated circuit corresponding to the test structure by adjusting at least one of the first distance and the second distance.

According to an eighth aspect, an embodiment of the present disclosure provides a test structure of an integrated circuit, including:

a first N-type heavily doped region, a first P-type heavily doped region, and a second N-type heavily doped region located between the first N-type heavily doped region and the first P-type heavily doped region;

wherein the second N-type heavily doped region is located in a first N well, the first N-type heavily doped region is located in a deep N well, the first P-type heavily doped region is located on a P-type substrate, the first N well is located on the P-type substrate, the deep N well is located in a second N well, and the second N well is located on the P-type substrate;

there is a first distance between the first N-type heavily doped region and the second N-type heavily doped region, and there is a second distance between the second N-type heavily doped region and the first P-type heavily doped region; and

the test structure is configured to test electrical parameters of the integrated circuit corresponding to the test structure by adjusting at least one of the first distance and the second distance.

According to a ninth aspect, an embodiment of the present disclosure provides a test structure of an integrated circuit, including:

a first N-type heavily doped region, a first P-type heavily doped region, and a second N-type heavily doped region located between the first N-type heavily doped region and the first P-type heavily doped region;

wherein the first N-type heavily doped region is located in a first deep N well, the second N-type heavily doped region is located in a second deep N well, the first P-type heavily doped region is located on a P-type substrate, the first deep N well is located in a first N well, the second deep N well is located in a second N well, and the first N well and the second N well are located on the P-type substrate;

there is a first distance between the first N-type heavily doped region and the second N-type heavily doped region, and there is a second distance between the second N-type heavily doped region and the first P-type heavily doped region; and

the test structure is configured to test electrical parameters of the integrated circuit corresponding to the test structure by adjusting at least one of the first distance and the second distance.

### BRIEF DESCRIPTION OF THE DRAWINGS

To describe the technical solutions in the embodiments of the present disclosure or in the prior art more clearly, the following briefly describes the accompanying drawings required for describing the embodiments or the prior art. Apparently, the accompanying drawings in the following description show some embodiments of the present disclosure, and a person of ordinary skill in the art may still derive other drawings from these accompanying drawings without creative efforts.

FIG. 1 is a schematic structural diagram of a wafer according to an embodiment of the present disclosure;

FIG. 2 is a first top view of a test structure of an integrated circuit according to an embodiment of the present disclosure;

FIG. 3 is a first cross-sectional view of a test structure of an integrated circuit according to an embodiment of the present disclosure;

FIG. 4 is a second top view of a test structure of an integrated circuit according to an embodiment of the present disclosure;

FIG. 5 is a second cross-sectional view of a test structure of an integrated circuit according to an embodiment of the present disclosure;

FIG. 6 is a third top view of a test structure of an integrated circuit according to an embodiment of the present disclosure;

FIG. 7 is a third cross-sectional view of a test structure of an integrated circuit according to an embodiment of the present disclosure;

FIG. 8 is a fourth top view of a test structure of an integrated circuit according to an embodiment of the present disclosure;

FIG. 9 is a fourth cross-sectional view of a test structure of an integrated circuit according to an embodiment of the present disclosure;

FIG. 10 is a fifth top view of a test structure of an integrated circuit according to an embodiment of the present disclosure;

FIG. 11 is a fifth cross-sectional view of a test structure of an integrated circuit according to an embodiment of the present disclosure;

FIG. 12 is a sixth top view of a test structure of an integrated circuit according to an embodiment of the present disclosure;

FIG. 13 is a sixth cross-sectional view of a test structure of an integrated circuit according to an embodiment of the present disclosure;

FIG. 14 is a seventh top view of a test structure of an integrated circuit according to an embodiment of the present disclosure;

FIG. 15 is a seventh cross-sectional view of a test structure of an integrated circuit according to an embodiment of the present disclosure;

FIG. 16 is an eighth top view of a test structure of an integrated circuit according to an embodiment of the present disclosure;

FIG. 17 is an eighth cross-sectional view of a test structure of an integrated circuit according to an embodiment of the present disclosure;

FIG. 18 is a ninth top view of a test structure of an integrated circuit according to an embodiment of the present disclosure; and

FIG. 19 is a ninth cross-sectional view of a test structure of an integrated circuit according to an embodiment of the present disclosure.

### DETAILED DESCRIPTION

In order to ensure the reliability of the chip, it is necessary to avoid the latch-up of the integrated circuit. Therefore, in a chip development stage, it is necessary to test various parasitic NPN transistor structures that may exist in the integrated circuit and extract corresponding rule parameters to design the integrated circuit, so as to avoid the latch-up.

Accordingly, a test structure of an integrated circuit provided by the embodiments of the present disclosure includes a first N-type heavily doped region, a first P-type heavily doped region, and a second N-type heavily doped region located between the first N-type heavily doped region and the first P-type heavily doped region; there is a first distance between the first N-type heavily doped region and the second N-type heavily doped region, and there is a second distance between the second N-type heavily doped region and the first P-type heavily doped region; electrical parameters of the integrated circuit corresponding to the test structure are tested by adjusting at least one of the first distance and the second distance. A correspondence between these electrical parameters and the first distance as well as the second distance can represent latch-up characteristics of the parasitic NPN transistor; the first distance and the second distance of the integrated circuit having the test structure can be set according to the latch-up characteristics, to avoid a latch-up in an operation process of the integrated circuit having the test structure, thereby improving the chip reliability.

Some optional implementations of the present disclosure are described below with reference to the accompanying drawings. Those skilled in the art should understand that the implementations below are merely illustrative rather than exhaustive enumerations. Based on these implementations, those skilled in the art can substitute, splice or combine certain features or certain examples, which shall still be considered as the disclosure of the present disclosure.

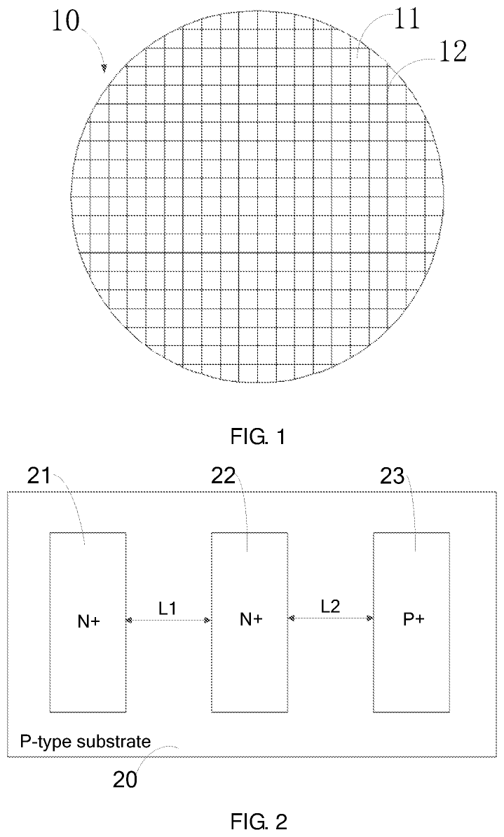

As shown in FIG. 1, a test structure of an integrated circuit provided by the embodiments of the present disclosure may be disposed on a wafer 10. The wafer 10 includes a plurality of dies 11, and a scribe line 12 between every two adjacent dies 11. Specifically, test structure of an integrated circuit provided by the embodiments of the present disclosure may be disposed in the scribe line 12. An equivalent circuit corresponding to the test structure of an integrated circuit is the same as an integrated circuit disposed on the die 11, so that electrical parameters of the integrated circuit on the die 11 can be tested by testing the test structure of the integrated circuit, thereby avoiding a latch-up in an operation process of the integrated circuit on the die 11.

It should be noted that, the electrical parameters under test may include a trigger voltage of the latch-up, a holding voltage of the latch-up, a trigger current of the latch-up, and a holding current of the latch-up. With a higher trigger voltage, the latch-up is less likely to occur; with a higher holding voltage, it is more difficult to maintain the latch-up. Assuming that a normal operating voltage is 1.1V, a trigger voltage of 1.2V corresponds to a higher risk of causing a latch-up, and a trigger voltage of 2V corresponds to a lower risk of causing a latch-up. Similarly, the same principle applies to the holding voltage. It should be noted that, the holding voltage is generally less than the trigger voltage.

The test structure of an integrated circuit includes a first N-type heavily doped region, a first P-type heavily doped region, and a second N-type heavily doped region located between the first N-type heavily doped region and the first P-type heavily doped region; there is a first distance between the first N-type heavily doped region and the second N-type heavily doped region, and there is a second distance between the second N-type heavily doped region and the first P-type heavily doped region; electrical parameters of the integrated circuit corresponding to the test structure are tested by adjusting at least one of the first distance and the second distance, wherein the electrical parameters are the trigger voltage of the latch-up, the holding voltage of the latch-up, the trigger current of the latch-up, and the holding current of the latch-up as described above. A correspondence between these electrical parameters and the first distance as well as the second distance can represent latch-up characteristics of the parasitic NPN transistor; the first distance and the second distance of the integrated circuit having the test structure can be set according to the latch-up characteristics, to avoid a latch-up in an operation process of the integrated circuit having the test structure, thereby improving the chip reliability.

It should be noted that, the test structure of an integrated circuit can be tested by using a Transmission Line Pulse (TLP): a contact terminal of the TLP is connected to a pin of the test structure of an integrated circuit, to inject a current to the pin, so as to test electrical parameters of a latch-up of the test structure of an integrated circuit.

The following briefly introduces 9 test structures of an integrated circuit. As shown in FIG. 2 to FIG. 19, N+ represents an N-type heavily doped region, and P+ represents a P-type heavily doped region.

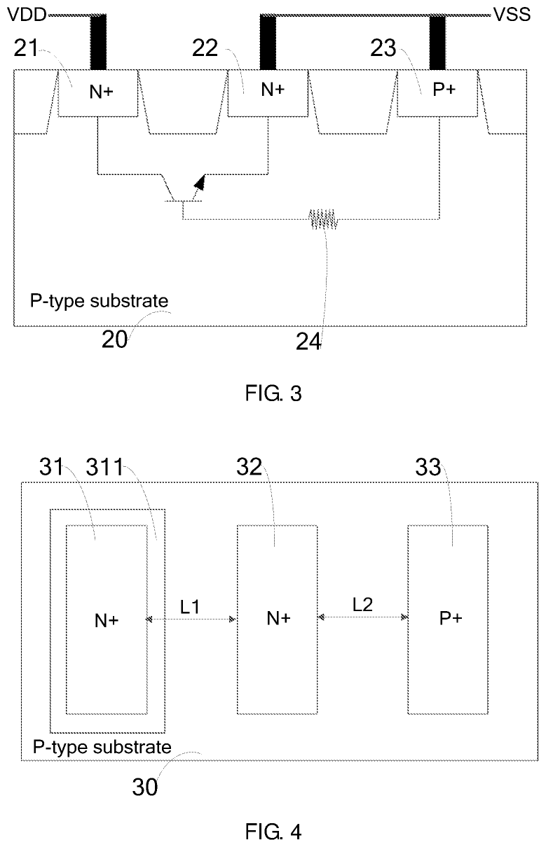

With reference to FIG. 2 and FIG. 3, a test structure of an integrated circuit provided by this embodiment includes: a first N-type heavily doped region 21, a first P-type heavily doped region 23, and a second N-type heavily doped region 22 located between the first N-type heavily doped region 21 and the first P-type heavily doped region 23. The first N-type heavily doped region 21, the second N-type heavily doped region 22, and the first P-type heavily doped region 23 are all located on a P-type substrate 20. There is a first distance between the first N-type heavily doped region 21 and the second N-type heavily doped region 22, and there is a second distance between the second N-type heavily doped region 22 and the first P-type heavily doped region 23. The test structure is configured to test electrical parameters of the integrated circuit corresponding to the test structure by adjusting at least one of the first distance and the second distance.

Further, the first N-type heavily doped region 21, the second N-type heavily doped region 22, and the first P-type heavily doped region 23 form a parasitic NPN transistor; the test structure is configured to test latch-up characteristics of the parasitic NPN transistor.

Further, the P-type substrate 20 has a parasitic resistor 24, and the parasitic resistor 24 has a first terminal connected to the first P-type heavily doped region 23 and a second terminal connected to a base of the parasitic NPN transistor.

Before the test structure of an integrated circuit in this embodiment needs to be powered on and connected before being tested. As shown in FIG. 3, the first N-type heavily doped region 21 may be connected to a power supply voltage VDD, and the second N-type heavily doped region 22 and the first P-type heavily doped region 23 are connected to a ground terminal VSS.

Specifically, the base of the parasitic NPN transistor is the P-type substrate 20, and a gain from the base to a collector may be dozens of times. In an equivalent circuit formed by the parasitic NPN transistor and the parasitic resistor 24, the parasitic NPN transistor has two states: a high-resistance blocking state, and a low-resistance latch-up state. When not triggered by an external interference, the parasitic NPN transistor is in the high-resistance blocking state, i.e., an initial state of the parasitic NPN transistor. In this case, a current gain is extremely small, and no latch-up occurs. When a collector current or voltage of the parasitic NPN transistor increases to a preset value abruptly, the parasitic NPN transistor may end the high-resistance blocking state and enter the low-resistance latch-up state. In this case, the parasitic NPN transistor will form a negative blocking state between the power supply voltage VDD and the ground terminal VSS. In this case, an amplified state of the parasitic NPN transistor can be continuously driven with a very small current, the emitter is forward-biased, and the collector is reverse-biased, thus generating a latch-up.

When the test structure of an integrated circuit in this embodiment is tested, and the first distance L1 and the second distance L2 have a first group of set values, a voltage applied to the power terminal VDD is gradually increased from 0V, for example, gradually increased from 0V to 2V, and a current between the power terminal VDD and the ground terminal VSS is monitored. When the current between the power terminal VDD and the ground terminal VSS increases abruptly, it is determined that a latch-up occurs. In this way, a correspondence between the first group of set values and the trigger voltage of the latch-up, the holding voltage of the latch-up, the trigger current of the latch-up, as well as the holding current of the latch-up can be obtained, that is, the latch-up characteristics of the parasitic NPN transistor are obtained. A second group of set values can be obtained by adjusting at least one of the first distance L1 and the second distance L2. Then, through the foregoing test method, a correspondence between the second group of set values and the trigger voltage of the latch-up, the holding voltage of the latch-up, the trigger current of the latch-up, as well as the holding current of the latch-up can be obtained. Similarly, a plurality of correspondences can be obtained; the first distance and the second distance of the integrated circuit having the test structure can be obtained according to the correspondences, to avoid a latch-up in an operation process of the integrated circuit having the test structure, thereby improving the chip reliability.

In the test structure of an integrated circuit provided by this embodiment, electrical parameters of the integrated circuit corresponding to the test structure are tested by adjusting at least one of the first distance and the second distance. A correspondence between these electrical parameters and the first distance as well as the second distance can represent latch-up characteristics of the parasitic NPN transistor; a design rule of the integrated circuit having the test structure can be defined according to the latch-up characteristics, to avoid a latch-up in an operation process of the integrated circuit having the test structure, thereby improving the chip reliability.

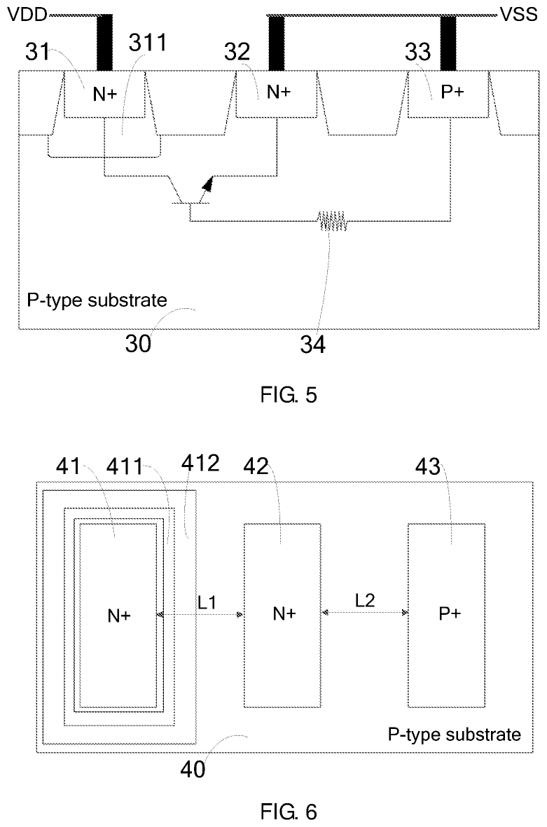

With reference to FIG. 4 and FIG. 5, a test structure of an integrated circuit provided by this embodiment includes: a first N-type heavily doped region 31, a first P-type heavily doped region 33, and a second N-type heavily doped region 32 located between the first N-type heavily doped region 31 and the first P-type heavily doped region 33. The first N-type heavily doped region 31 is located in an N well 311, the second N-type heavily doped region 32 and the first P-type heavily doped region 33 are both located on a P-type substrate 30, and the N well 311 is located on the P-type substrate 30. There is a first distance between the first N-type heavily doped region 31 and the second N-type heavily doped region 32, and there is a second distance between the second N-type heavily doped region 32 and the first P-type heavily doped region 33. The test structure is configured to test electrical parameters of the integrated circuit corresponding to the test structure by adjusting at least one of the first distance and the second distance.

Further, the N well 311, the second N-type heavily doped region 32, and the first P-type heavily doped region 33 form a parasitic NPN transistor, and the test structure is configured to test latch-up characteristics of the parasitic NPN transistor.

Further, the P-type substrate 30 has a parasitic resistor 34, and the parasitic resistor 34 has a first terminal connected to the first P-type heavily doped region 33 and a second terminal connected to a base of the parasitic NPN transistor.

Before the test structure of an integrated circuit in this embodiment needs to be powered on and connected before being tested. As shown in FIG. 5, the first N-type heavily doped region 31 may be connected to a power supply voltage VDD, and the second N-type heavily doped region 32 and the first P-type heavily doped region 33 are connected to a ground terminal VSS.

Specifically, the base of the parasitic NPN transistor is the P-type substrate 30, and a gain from the base to a collector may be dozens of times. In an equivalent circuit formed by the parasitic NPN transistor and the parasitic resistor 34, the parasitic NPN transistor has two states: a high-resistance blocking state, and a low-resistance latch-up state. When not triggered by an external interference, the parasitic NPN transistor is in the high-resistance blocking state, i.e., an initial state of the parasitic NPN transistor. In this case, a current gain is extremely small, and no latch-up occurs. When a collector current of the parasitic NPN transistor increases to a preset value abruptly, the parasitic NPN transistor may end the high-resistance blocking state and enter the low-resistance latch-up state. In this case, the parasitic NPN transistor will form a negative blocking state between the power supply voltage VDD and the ground terminal VSS. In this case, an amplified state of the parasitic NPN transistor can be continuously driven with a very small current, the emitter is forward-biased, and the collector is reverse-biased, thus generating a latch-up.

When the test structure of an integrated circuit in this embodiment is tested, and the first distance L1 and the second distance L2 have a first group of set values, a voltage applied to the power terminal VDD is gradually increased from 0V, for example, gradually increased from 0V to 2V, and a current between the power terminal VDD and the ground terminal VSS is monitored. When the current between the power terminal VDD and the ground terminal VSS increases abruptly, it is determined that a latch-up occurs. In this way, a correspondence between the first group of set values and the trigger voltage of the latch-up, the holding voltage of the latch-up, the trigger current of the latch-up, as well as the holding current of the latch-up can be obtained, that is, the latch-up characteristics of the parasitic NPN transistor are obtained. A second group of set values can be obtained by adjusting at least one of the first distance L1 and the second distance L2. Then, through the foregoing test method, a correspondence between the second group of set values and the trigger voltage of the latch-up, the holding voltage of the latch-up, the trigger current of the latch-up, as well as the holding current of the latch-up can be obtained. Similarly, a plurality of correspondences can be obtained; the first distance and the second distance of the integrated circuit having the test structure can be obtained according to the correspondences, to avoid a latch-up in an operation process of the integrated circuit having the test structure, thereby improving the chip reliability.

In the test structure of an integrated circuit provided by this embodiment, electrical parameters of the integrated circuit corresponding to the test structure are tested by adjusting at least one of the first distance and the second distance. A correspondence between these electrical parameters and the first distance as well as the second distance can represent latch-up characteristics of the parasitic NPN transistor; a design rule of the integrated circuit having the test structure can be defined according to the latch-up characteristics, to avoid a latch-up in an operation process of the integrated circuit having the test structure, thereby improving the chip reliability.

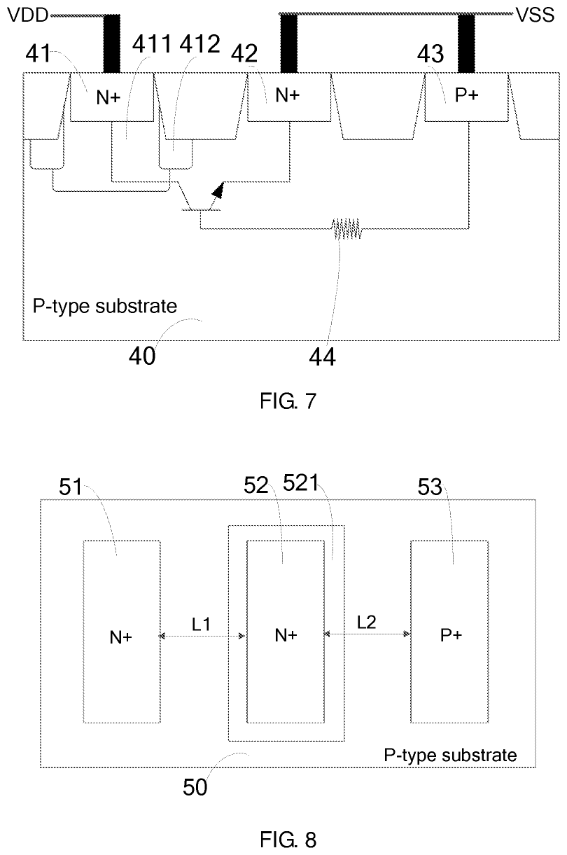

With reference to FIG. 6 and FIG. 7, a test structure of an integrated circuit provided by this embodiment includes: a first N-type heavily doped region 41, a first P-type heavily doped region 43, and a second N-type heavily doped region 42 located between the first N-type heavily doped region 41 and the first P-type heavily doped region 43. The first N-type heavily doped region 41 is located in a deep N well 411, and the second N-type heavily doped region 42 and the first P-type heavily doped region 43 are both located on a P-type substrate 40, wherein the deep N well 411 is located in an N well 412, and the N well 412 is located on the P-type substrate 40. There is a first distance between the first N-type heavily doped region 41 and the second N-type heavily doped region 42, and there is a second distance between the second N-type heavily doped region 42 and the first P-type heavily doped region 43. The test structure is configured to test electrical parameters of the integrated circuit corresponding to the test structure by adjusting at least one of the first distance and the second distance.

Further, the deep N well 411, the second N-type heavily doped region 42, and the first P-type heavily doped region 43 form a parasitic NPN transistor, and the test structure is configured to test latch-up characteristics of the parasitic NPN transistor.

Further, the P-type substrate 40 has a parasitic resistor 44, and the parasitic resistor 44 has a first terminal connected to the first P-type heavily doped region 43 and a second terminal connected to a base of the parasitic NPN transistor.

Before the test structure of an integrated circuit in this embodiment needs to be powered on and connected before being tested. As shown in FIG. 7, the first N-type heavily doped region 41 may be connected to a power supply voltage VDD, and the second N-type heavily doped region 42 and the first P-type heavily doped region 43 are connected to a ground terminal VSS.

Specifically, the base of the parasitic NPN transistor is the P-type substrate 40, and a gain from the base to a collector may be dozens of times. In an equivalent circuit formed by the parasitic NPN transistor and the parasitic resistor 44, the parasitic NPN transistor has two states: a high-resistance blocking state, and a low-resistance latch-up state. When not triggered by an external interference, the parasitic NPN transistor is in the high-resistance blocking state, i.e., an initial state of the parasitic NPN transistor. In this case, a current gain is extremely small, and no latch-up occurs. When a collector current of the parasitic NPN transistor increases to a preset value abruptly, the parasitic NPN transistor may end the high-resistance blocking state and enter the low-resistance latch-up state. In this case, the parasitic NPN transistor will form a negative blocking state between the power supply voltage VDD and the ground terminal VSS. In this case, an amplified state of the parasitic NPN transistor can be continuously driven with a very small current, the emitter is forward-biased, and the collector is reverse-biased, thus generating a latch-up.

When the test structure of an integrated circuit in this embodiment is tested, and the first distance L1 and the second distance L2 have a first group of set values, a voltage applied to the power terminal VDD is gradually increased from 0V, for example, gradually increased from 0V to 2V, and a current between the power terminal VDD and the ground terminal VSS is monitored. When the current between the power terminal VDD and the ground terminal VSS increases abruptly, it is determined that a latch-up occurs. In this way, a correspondence between the first group of set values and the trigger voltage of the latch-up, the holding voltage of the latch-up, the trigger current of the latch-up, as well as the holding current of the latch-up can be obtained, that is, the latch-up characteristics of the parasitic NPN transistor are obtained. A second group of set values can be obtained by adjusting at least one of the first distance L1 and the second distance L2. Then, through the foregoing test method, a correspondence between the second group of set values and the trigger voltage of the latch-up, the holding voltage of the latch-up, the trigger current of the latch-up, as well as the holding current of the latch-up can be obtained. Similarly, a plurality of correspondences can be obtained; the first distance and the second distance of the integrated circuit having the test structure can be obtained according to the correspondences, to avoid a latch-up in an operation process of the integrated circuit having the test structure, thereby improving the chip reliability.

In the test structure of an integrated circuit provided by this embodiment, electrical parameters of the integrated circuit corresponding to the test structure are tested by adjusting at least one of the first distance and the second distance. A correspondence between these electrical parameters and the first distance as well as the second distance can represent latch-up characteristics of the parasitic NPN transistor; a design rule of the integrated circuit having the test structure can be defined according to the latch-up characteristics, to avoid a latch-up in an operation process of the integrated circuit having the test structure, thereby improving the chip reliability.

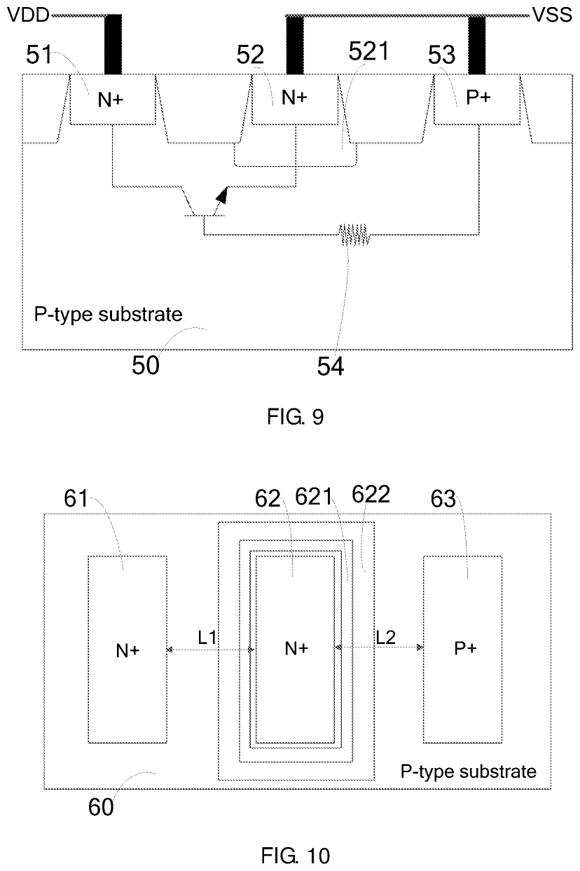

With reference to FIG. 8 and FIG. 9, a test structure of an integrated circuit provided by this embodiment includes: a first N-type heavily doped region 51, a first P-type heavily doped region 53, and a second N-type heavily doped region 52 located between the first N-type heavily doped region 51 and the first P-type heavily doped region 53. The second N-type heavily doped region 52 is located in an N well 521, the first N-type heavily doped region 51 and the first P-type heavily doped region 53 are both located on a P-type substrate 50, and the N well 521 is located on the P-type substrate 50. There is a first distance between the first N-type heavily doped region 51 and the second N-type heavily doped region 52, and there is a second distance between the second N-type heavily doped region 52 and the first P-type heavily doped region 53. The test structure is configured to test electrical parameters of the integrated circuit corresponding to the test structure by adjusting at least one of the first distance and the second distance.

Further, the N well 521, the first N-type heavily doped region 51, and the first P-type heavily doped region 53 form a parasitic NPN transistor, and the test structure is configured to test latch-up characteristics of the parasitic NPN transistor.

Further, the P-type substrate 50 has a parasitic resistor 54, and the parasitic resistor 54 has a first terminal connected to the first P-type heavily doped region 53 and a second terminal connected to a base of the parasitic NPN transistor.

Before the test structure of an integrated circuit in this embodiment needs to be powered on and connected before being tested. As shown in FIG. 9, the first N-type heavily doped region 51 may be connected to a power supply voltage VDD, and the second N-type heavily doped region 52 and the first P-type heavily doped region 53 are connected to a ground terminal VSS.

Specifically, the base of the parasitic NPN transistor is the P-type substrate 50, and a gain from the base to a collector may be dozens of times. In an equivalent circuit formed by the parasitic NPN transistor and the parasitic resistor 54, the parasitic NPN transistor has two states: a high-resistance blocking state, and a low-resistance latch-up state. When not triggered by an external interference, the parasitic NPN transistor is in the high-resistance blocking state, i.e., an initial state of the parasitic NPN transistor. In this case, a current gain is extremely small, and no latch-up occurs. When a collector current of the parasitic NPN transistor increases to a preset value abruptly, the parasitic NPN transistor may end the high-resistance blocking state and enter the low-resistance latch-up state. In this case, the parasitic NPN transistor will form a negative blocking state between the power supply voltage VDD and the ground terminal VSS. In this case, an amplified state of the parasitic NPN transistor can be continuously driven with a very small current, the emitter is forward-biased, and the collector is reverse-biased, thus generating a latch-up.

When the test structure of an integrated circuit in this embodiment is tested, and the first distance L1 and the second distance L2 have a first group of set values, a voltage applied to the power terminal VDD is gradually increased from 0V, for example, gradually increased from 0V to 2V, and a current between the power terminal VDD and the ground terminal VSS is monitored. When the current between the power terminal VDD and the ground terminal VSS increases abruptly, it is determined that a latch-up occurs. In this way, a correspondence between the first group of set values and the trigger voltage of the latch-up, the holding voltage of the latch-up, the trigger current of the latch-up, as well as the holding current of the latch-up can be obtained, that is, the latch-up characteristics of the parasitic NPN transistor are obtained. A second group of set values can be obtained by adjusting at least one of the first distance L1 and the second distance L2. Then, through the foregoing test method, a correspondence between the second group of set values and the trigger voltage of the latch-up, the holding voltage of the latch-up, the trigger current of the latch-up, as well as the holding current of the latch-up can be obtained. Similarly, a plurality of correspondences can be obtained; the first distance and the second distance of the integrated circuit having the test structure can be obtained according to the correspondences, to avoid a latch-up in an operation process of the integrated circuit having the test structure, thereby improving the chip reliability.

In the test structure of an integrated circuit provided by this embodiment, electrical parameters of the integrated circuit corresponding to the test structure are tested by adjusting at least one of the first distance and the second distance. A correspondence between these electrical parameters and the first distance as well as the second distance can represent latch-up characteristics of the parasitic NPN transistor; a design rule of the integrated circuit having the test structure can be defined according to the latch-up characteristics, to avoid a latch-up in an operation process of the integrated circuit having the test structure, thereby improving the chip reliability.

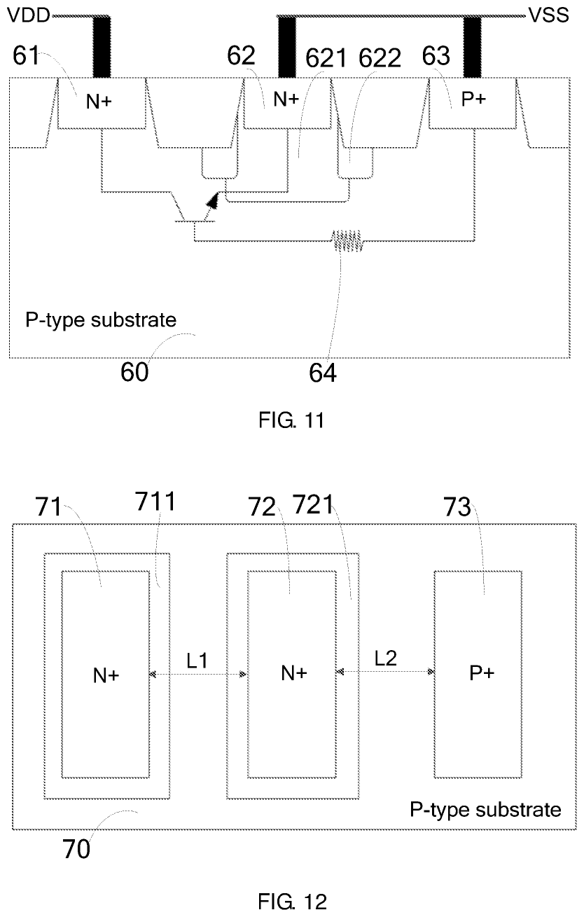

With reference to FIG. 10 and FIG. 11, a test structure of an integrated circuit provided by this embodiment includes: a first N-type heavily doped region 61, a first P-type heavily doped region 63, and a second N-type heavily doped region 62 located between the first N-type heavily doped region 61 and the first P-type heavily doped region 63. The second N-type heavily doped region 62 is located in a deep N well 621, and the first N-type heavily doped region 61 and the first P-type heavily doped region 63 are both located on a P-type substrate 60, wherein the deep N well 621 is located in an N well 622, and the N well 622 is located on the P-type substrate 60. There is a first distance between the first N-type heavily doped region 61 and the second N-type heavily doped region 62, and there is a second distance between the second N-type heavily doped region 62 and the first P-type heavily doped region 63. The test structure is configured to test electrical parameters of the integrated circuit corresponding to the test structure by adjusting at least one of the first distance and the second distance.

Further, the deep N well 621, the first N-type heavily doped region 61, and the first P-type heavily doped region 63 form a parasitic NPN transistor; the test structure is configured to test latch-up characteristics of the parasitic NPN transistor.

Further, the P-type substrate 60 has a parasitic resistor 64, and the parasitic resistor 64 has a first terminal connected to the first P-type heavily doped region 63 and a second terminal connected to a base of the parasitic NPN transistor.

Before the test structure of an integrated circuit in this embodiment needs to be powered on and connected before being tested. As shown in FIG. 11, the first N-type heavily doped region 61 may be connected to a power supply voltage VDD, and the second N-type heavily doped region 62 and the first P-type heavily doped region 63 are connected to a ground terminal VSS.

Specifically, the base of the parasitic NPN transistor is the P-type substrate 60, and a gain from the base to a collector may be dozens of times. In an equivalent circuit formed by the parasitic NPN transistor and the parasitic resistor 64, the parasitic NPN transistor has two states: a high-resistance blocking state, and a low-resistance latch-up state. When not triggered by an external interference, the parasitic NPN transistor is in the high-resistance blocking state, i.e., an initial state of the parasitic NPN transistor. In this case, a current gain is extremely small, and no latch-up occurs. When a collector current of the parasitic NPN transistor increases to a preset value abruptly, the parasitic NPN transistor may end the high-resistance blocking state and enter the low-resistance latch-up state. In this case, the parasitic NPN transistor will form a negative blocking state between the power supply voltage VDD and the ground terminal VSS. In this case, an amplified state of the parasitic NPN transistor can be continuously driven with a very small current, the emitter is forward-biased, and the collector is reverse-biased, thus generating a latch-up.

When the test structure of an integrated circuit in this embodiment is tested, and the first distance L1 and the second distance L2 have a first group of set values, a voltage applied to the power terminal VDD is gradually increased from 0V, for example, gradually increased from 0V to 2V, and a current between the power terminal VDD and the ground terminal VSS is monitored. When the current between the power terminal VDD and the ground terminal VSS increases abruptly, it is determined that a latch-up occurs. In this way, a correspondence between the first group of set values and the trigger voltage of the latch-up, the holding voltage of the latch-up, the trigger current of the latch-up, as well as the holding current of the latch-up can be obtained, that is, the latch-up characteristics of the parasitic NPN transistor are obtained. A second group of set values can be obtained by adjusting at least one of the first distance L1 and the second distance L2. Then, through the foregoing test method, a correspondence between the second group of set values and the trigger voltage of the latch-up, the holding voltage of the latch-up, the trigger current of the latch-up, as well as the holding current of the latch-up can be obtained. Similarly, a plurality of correspondences can be obtained; the first distance and the second distance of the integrated circuit having the test structure can be obtained according to the correspondences, to avoid a latch-up in an operation process of the integrated circuit having the test structure, thereby improving the chip reliability.

In the test structure of an integrated circuit provided by this embodiment, electrical parameters of the integrated circuit corresponding to the test structure are tested by adjusting at least one of the first distance and the second distance. A correspondence between these electrical parameters and the first distance as well as the second distance can represent latch-up characteristics of the parasitic NPN transistor; a design rule of the integrated circuit having the test structure can be defined according to the latch-up characteristics, to avoid a latch-up in an operation process of the integrated circuit having the test structure, thereby improving the chip reliability.

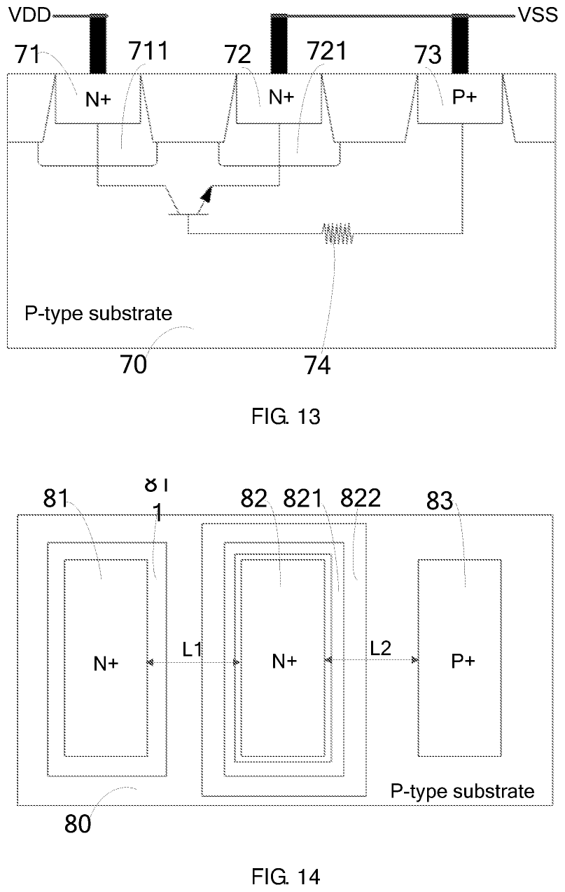

With reference to FIG. 12 and FIG. 13, a test structure of an integrated circuit provided by this embodiment includes: a first N-type heavily doped region 71, a first P-type heavily doped region 73, and a second N-type heavily doped region 72 located between the first N-type heavily doped region 71 and the first P-type heavily doped region 73. The first N-type heavily doped region 71 is located in a first N well 711, the second N-type heavily doped region 72 is located in a second N well 721, and the first P-type heavily doped region 73 is located on a P-type substrate 70, wherein the first N well 711 and the second N well 721 are located on the P-type substrate 70. There is a first distance between the first N-type heavily doped region 71 and the second N-type heavily doped region 72, and there is a second distance between the second N-type heavily doped region 72 and the first P-type heavily doped region 73. The test structure is configured to test electrical parameters of the integrated circuit corresponding to the test structure by adjusting at least one of the first distance and the second distance.

Further, the first N well 711, the second N well 721, and the first P-type heavily doped region 73 form a parasitic NPN transistor; the test structure is configured to test latch-up characteristics of the parasitic NPN transistor.

Further, the P-type substrate 70 has a parasitic resistor 74, and the parasitic resistor 74 has a first terminal connected to the first P-type heavily doped region 73, and a second terminal connected to a base of the parasitic NPN transistor.

Before the test structure of an integrated circuit in this embodiment needs to be powered on and connected before being tested. As shown in FIG. 13, the first N-type heavily doped region 71 may be connected to a power supply voltage VDD, and the second N-type heavily doped region 72 and the first P-type heavily doped region 73 are connected to a ground terminal VSS.

Specifically, the base of the parasitic NPN transistor is the P-type substrate 70, and a gain from the base to a collector may be dozens of times. In an equivalent circuit formed by the parasitic NPN transistor and the parasitic resistor 74, the parasitic NPN transistor has two states: a high-resistance blocking state, and a low-resistance latch-up state. When not triggered by an external interference, the parasitic NPN transistor is in the high-resistance blocking state, i.e., an initial state of the parasitic NPN transistor. In this case, a current gain is extremely small, and no latch-up occurs. When a collector current of the parasitic NPN transistor increases to a preset value abruptly, the parasitic NPN transistor may end the high-resistance blocking state and enter the low-resistance latch-up state. In this case, the parasitic NPN transistor will form a negative blocking state between the power supply voltage VDD and the ground terminal VSS. In this case, an amplified state of the parasitic NPN transistor can be continuously driven with a very small current, the emitter is forward-biased, and the collector is reverse-biased, thus generating a latch-up.

When the test structure of an integrated circuit in this embodiment is tested, and the first distance L1 and the second distance L2 have a first group of set values, a voltage applied to the power terminal VDD is gradually increased from 0V, for example, gradually increased from 0V to 2V, and a current between the power terminal VDD and the ground terminal VSS is monitored. When the current between the power terminal VDD and the ground terminal VSS increases abruptly, it is determined that a latch-up occurs. In this way, a correspondence between the first group of set values and the trigger voltage of the latch-up, the holding voltage of the latch-up, the trigger current of the latch-up, as well as the holding current of the latch-up can be obtained, that is, the latch-up characteristics of the parasitic NPN transistor are obtained. A second group of set values can be obtained by adjusting at least one of the first distance L1 and the second distance L2. Then, through the foregoing test method, a correspondence between the second group of set values and the trigger voltage of the latch-up, the holding voltage of the latch-up, the trigger current of the latch-up, as well as the holding current of the latch-up can be obtained. Similarly, a plurality of correspondences can be obtained; the first distance and the second distance of the integrated circuit having the test structure can be obtained according to the correspondences, to avoid a latch-up in an operation process of the integrated circuit having the test structure, thereby improving the chip reliability.

In the test structure of an integrated circuit provided by this embodiment, electrical parameters of the integrated circuit corresponding to the test structure are tested by adjusting at least one of the first distance and the second distance. A correspondence between these electrical parameters and the first distance as well as the second distance can represent latch-up characteristics of the parasitic NPN transistor; a design rule of the integrated circuit having the test structure can be defined according to the latch-up characteristics, to avoid a latch-up in an operation process of the integrated circuit having the test structure, thereby improving the chip reliability.

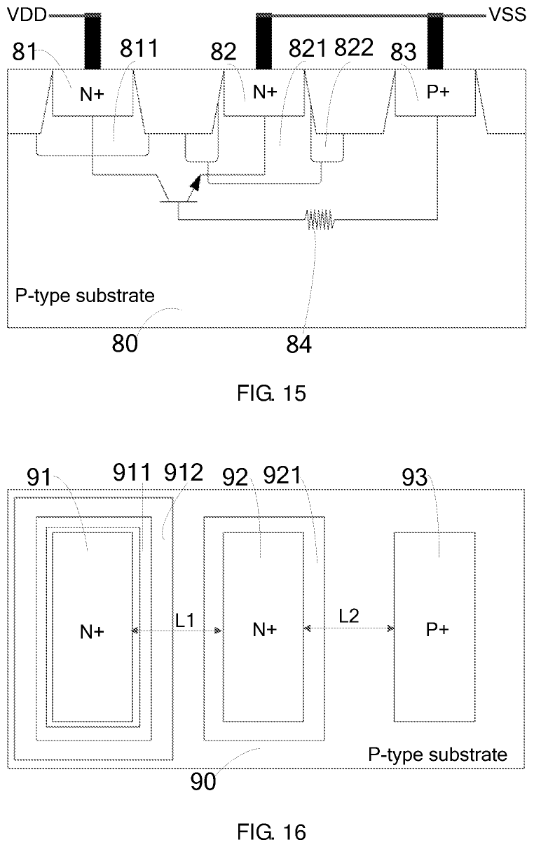

With reference to FIG. 14 and FIG. 15, a test structure of an integrated circuit provided by this embodiment includes: a first N-type heavily doped region 81, a first P-type heavily doped region 83, and a second N-type heavily doped region 82 located between the first N-type heavily doped region 81 and the first P-type heavily doped region 83. The first N-type heavily doped region 81 is located in a first N well 811, the second N-type heavily doped region 82 is located in a deep N well 821, and the first P-type heavily doped region 83 is located on a P-type substrate 80, wherein the first N well 811 is located on the P-type substrate 80, the deep N well 821 is located in a second N well 822, and the second N well 822 is located on the P-type substrate 80. There is a first distance between the first N-type heavily doped region 81 and the second N-type heavily doped region 82, and there is a second distance between the second N-type heavily doped region 82 and the first P-type heavily doped region 83. The test structure is configured to test electrical parameters of the integrated circuit corresponding to the test structure by adjusting at least one of the first distance and the second distance.

Further, the first N well 811, the deep N well 821, and the first P-type heavily doped region 83 form a parasitic NPN transistor; the test structure is configured to test latch-up characteristics of the parasitic NPN transistor.

Further, the P-type substrate 80 has a parasitic resistor 84, and the parasitic resistor 84 has a first terminal connected to the first P-type heavily doped region 83 and a second terminal connected to a base of the parasitic NPN transistor.

Before the test structure of an integrated circuit in this embodiment needs to be powered on and connected before being tested. As shown in FIG. 15, the first N-type heavily doped region 81 may be connected to a power supply voltage VDD, and the second N-type heavily doped region 82 and the first P-type heavily doped region 83 are connected to a ground terminal VSS.

Specifically, the base of the parasitic NPN transistor is the P-type substrate 80, and a gain from the base to a collector may be dozens of times. In an equivalent circuit formed by the parasitic NPN transistor and the parasitic resistor 84, the parasitic NPN transistor has two states: a high-resistance blocking state, and a low-resistance latch-up state. When not triggered by an external interference, the parasitic NPN transistor is in the high-resistance blocking state, i.e., an initial state of the parasitic NPN transistor. In this case, a current gain is extremely small, and no latch-up occurs. When a collector current of the parasitic NPN transistor increases to a preset value abruptly, the parasitic NPN transistor may end the high-resistance blocking state and enter the low-resistance latch-up state. In this case, the parasitic NPN transistor will form a negative blocking state between the power supply voltage VDD and the ground terminal VSS. In this case, an amplified state of the parasitic NPN transistor can be continuously driven with a very small current, the emitter is forward-biased, and the collector is reverse-biased, thus generating a latch-up.

When the test structure of an integrated circuit in this embodiment is tested, and the first distance L1 and the second distance L2 have a first group of set values, a voltage applied to the power terminal VDD is gradually increased from 0V, for example, gradually increased from 0V to 2V, and a current between the power terminal VDD and the ground terminal VSS is monitored. When the current between the power terminal VDD and the ground terminal VSS increases abruptly, it is determined that a latch-up occurs. In this way, a correspondence between the first group of set values and the trigger voltage of the latch-up, the holding voltage of the latch-up, the trigger current of the latch-up, as well as the holding current of the latch-up can be obtained, that is, the latch-up characteristics of the parasitic NPN transistor are obtained. A second group of set values can be obtained by adjusting at least one of the first distance L1 and the second distance L2. Then, through the foregoing test method, a correspondence between the second group of set values and the trigger voltage of the latch-up, the holding voltage of the latch-up, the trigger current of the latch-up, as well as the holding current of the latch-up can be obtained. Similarly, a plurality of correspondences can be obtained; the first distance and the second distance of the integrated circuit having the test structure can be obtained according to the correspondences, to avoid a latch-up in an operation process of the integrated circuit having the test structure, thereby improving the chip reliability.

In the test structure of an integrated circuit provided by this embodiment, electrical parameters of the integrated circuit corresponding to the test structure are tested by adjusting at least one of the first distance and the second distance. A correspondence between these electrical parameters and the first distance as well as the second distance can represent latch-up characteristics of the parasitic NPN transistor; a design rule of the integrated circuit having the test structure can be defined according to the latch-up characteristics, to avoid a latch-up in an operation process of the integrated circuit having the test structure, thereby improving the chip reliability.

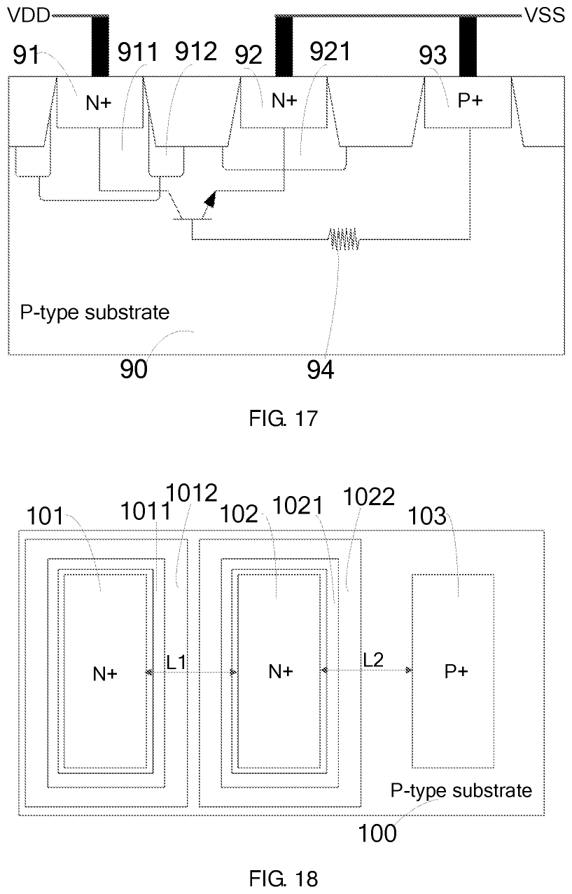

With reference to FIG. 16 and FIG. 17, a test structure of an integrated circuit provided by this embodiment includes: a first N-type heavily doped region 91, a first P-type heavily doped region 93, and a second N-type heavily doped region 92 located between the first N-type heavily doped region 91 and the first P-type heavily doped region 93. The second N-type heavily doped region 92 is located in a first N well 921, the first N-type heavily doped region 91 is located in a deep N well 911, and the first P-type heavily doped region 93 is located on a P-type substrate 90, wherein the first N well 921 is located on the P-type substrate 90, the deep N well 911 is located in a second N well 912, and the second N well 912 is located on the P-type substrate 90. There is a first distance between the first N-type heavily doped region 91 and the second N-type heavily doped region 92, and there is a second distance between the second N-type heavily doped region 92 and the first P-type heavily doped region 93. The test structure is configured to test electrical parameters of the integrated circuit corresponding to the test structure by adjusting at least one of the first distance and the second distance.

Further, the first N well 921, the deep N well 911, and the first P-type heavily doped region 93 form a parasitic NPN transistor; the test structure is configured to test latch-up characteristics of the parasitic NPN transistor.

Further, the P-type substrate 90 has a parasitic resistor 94, and the parasitic resistor 94 has a first terminal connected to the first P-type heavily doped region 93 and a second terminal connected to a base of the parasitic NPN transistor.

Before the test structure of an integrated circuit in this embodiment needs to be powered on and connected before being tested. As shown in FIG. 17, the first N-type heavily doped region 91 may be connected to a power supply voltage VDD, and the second N-type heavily doped region 92 and the first P-type heavily doped region 93 are connected to a ground terminal VSS.

Specifically, the base of the parasitic NPN transistor is the P-type substrate 90, and a gain from the base to a collector may be dozens of times. In an equivalent circuit formed by the parasitic NPN transistor and the parasitic resistor 94, the parasitic NPN transistor has two states: a high-resistance blocking state, and a low-resistance latch-up state. When not triggered by an external interference, the parasitic NPN transistor is in the high-resistance blocking state, i.e., an initial state of the parasitic NPN transistor. In this case, a current gain is extremely small, and no latch-up occurs. When a collector current of the parasitic NPN transistor increases to a preset value abruptly, the parasitic NPN transistor may end the high-resistance blocking state and enter the low-resistance latch-up state. In this case, the parasitic NPN transistor will form a negative blocking state between the power supply voltage VDD and the ground terminal VSS. In this case, an amplified state of the parasitic NPN transistor can be continuously driven with a very small current, the emitter is forward-biased, and the collector is reverse-biased, thus generating a latch-up.

When the test structure of an integrated circuit in this embodiment is tested, and the first distance L1 and the second distance L2 have a first group of set values, a voltage applied to the power terminal VDD is gradually increased from 0V, for example, gradually increased from 0V to 2V, and a current between the power terminal VDD and the ground terminal VSS is monitored. When the current between the power terminal VDD and the ground terminal VSS increases abruptly, it is determined that a latch-up occurs. In this way, a correspondence between the first group of set values and the trigger voltage of the latch-up, the holding voltage of the latch-up, the trigger current of the latch-up, as well as the holding current of the latch-up can be obtained, that is, the latch-up characteristics of the parasitic NPN transistor are obtained. A second group of set values can be obtained by adjusting at least one of the first distance L1 and the second distance L2. Then, through the foregoing test method, a correspondence between the second group of set values and the trigger voltage of the latch-up, the holding voltage of the latch-up, the trigger current of the latch-up, as well as the holding current of the latch-up can be obtained. Similarly, a plurality of correspondences can be obtained; the first distance and the second distance of the integrated circuit having the test structure can be obtained according to the correspondences, to avoid a latch-up in an operation process of the integrated circuit having the test structure, thereby improving the chip reliability.

In the test structure of an integrated circuit provided by this embodiment, electrical parameters of the integrated circuit corresponding to the test structure are tested by adjusting at least one of the first distance and the second distance. A correspondence between these electrical parameters and the first distance as well as the second distance can represent latch-up characteristics of the parasitic NPN transistor; a design rule of the integrated circuit having the test structure can be defined according to the latch-up characteristics, to avoid a latch-up in an operation process of the integrated circuit having the test structure, thereby improving the chip reliability.

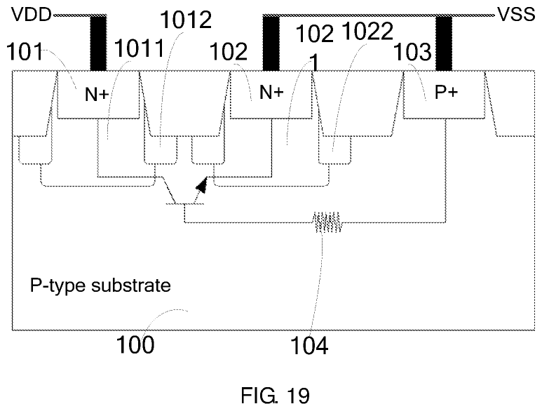

With reference to FIG. 18 and FIG. 19, a test structure of an integrated circuit provided by this embodiment includes: a first N-type heavily doped region 101, a first P-type heavily doped region 103, and a second N-type heavily doped region 102 located between the first N-type heavily doped region 101 and the first P-type heavily doped region 103. The first N-type heavily doped region 101 is located in a first deep N well 1011, the second N-type heavily doped region 102 is located in a second deep N well 1021, and the first P-type heavily doped region 103 is located on a P-type substrate 100, wherein the first deep N well 1011 is located in a first N well 1012, the second deep N well 1021 is located in a second N well 1022, and the first N well 1012 and the second N well 1022 are located on the P-type substrate 100. There is a first distance between the first N-type heavily doped region 101 and the second N-type heavily doped region 102, and there is a second distance between the second N-type heavily doped region 102 and the first P-type heavily doped region 103. The test structure is configured to test electrical parameters of the integrated circuit corresponding to the test structure by adjusting at least one of the first distance and the second distance.

Further, the first deep N well 1011, the second deep N well 1021, and the first P-type heavily doped region 103 form a parasitic NPN transistor; the test structure is configured to test latch-up characteristics of the parasitic NPN transistor.

Further, the P-type substrate 100 has a parasitic resistor 104, and the parasitic resistor 104 has a first terminal connected to the first P-type heavily doped region 103 and a second terminal connected to a base of the parasitic NPN transistor.

Before the test structure of an integrated circuit in this embodiment needs to be powered on and connected before being tested. As shown in FIG. 19, the first N-type heavily doped region 101 may be connected to a power supply voltage VDD, and the second N-type heavily doped region 102 and the first P-type heavily doped region 103 are connected to a ground terminal VSS.

Specifically, the base of the parasitic NPN transistor is the P-type substrate 100, and a gain from the base to a collector may be dozens of times. In an equivalent circuit formed by the parasitic NPN transistor and the parasitic resistor 104, the parasitic NPN transistor has two states: a high-resistance blocking state, and a low-resistance latch-up state. When not triggered by an external interference, the parasitic NPN transistor is in the high-resistance blocking state, i.e., an initial state of the parasitic NPN transistor. In this case, a current gain is extremely small, and no latch-up occurs. When a collector current of the parasitic NPN transistor increases to a preset value abruptly, the parasitic NPN transistor may end the high-resistance blocking state and enter the low-resistance latch-up state. In this case, the parasitic NPN transistor will form a negative blocking state between the power supply voltage VDD and the ground terminal VSS. In this case, an amplified state of the parasitic NPN transistor can be continuously driven with a very small current, the emitter is forward-biased, and the collector is reverse-biased, thus generating a latch-up.

When the test structure of an integrated circuit in this embodiment is tested, and the first distance L1 and the second distance L2 have a first group of set values, a voltage applied to the power terminal VDD is gradually increased from 0V, for example, gradually increased from 0V to 2V, and a current between the power terminal VDD and the ground terminal VSS is monitored. When the current between the power terminal VDD and the ground terminal VSS increases abruptly, it is determined that a latch-up occurs. In this way, a correspondence between the first group of set values and the trigger voltage of the latch-up, the holding voltage of the latch-up, the trigger current of the latch-up, as well as the holding current of the latch-up can be obtained, that is, the latch-up characteristics of the parasitic NPN transistor are obtained. A second group of set values can be obtained by adjusting at least one of the first distance L1 and the second distance L2. Then, through the foregoing test method, a correspondence between the second group of set values and the trigger voltage of the latch-up, the holding voltage of the latch-up, the trigger current of the latch-up, as well as the holding current of the latch-up can be obtained. Similarly, a plurality of correspondences can be obtained; the first distance and the second distance of the integrated circuit having the test structure can be obtained according to the correspondences, to avoid a latch-up in an operation process of the integrated circuit having the test structure, thereby improving the chip reliability.

In the test structure of an integrated circuit provided by this embodiment, electrical parameters of the integrated circuit corresponding to the test structure are tested by adjusting at least one of the first distance and the second distance. A correspondence between these electrical parameters and the first distance as well as the second distance can represent latch-up characteristics of the parasitic NPN transistor; a design rule of the integrated circuit having the test structure can be defined according to the latch-up characteristics, to avoid a latch-up in an operation process of the integrated circuit having the test structure, thereby improving the chip reliability.

A person skilled in the art can clearly understand that, for convenience and brevity of description, the division of the foregoing functional modules is merely an example for description. In practical application, the functions may be assigned to and completed by different functional modules as required. That is, the internal structure of the apparatus is divided into different functional modules, to complete all or some of the functions described above. Reference may be made to the corresponding process in the foregoing method embodiments for the specific working process of the foregoing apparatus. Details are not described herein again.

Finally, it should be noted that the foregoing embodiments are used only to explain the technical solutions of the present disclosure, but are not intended to limit the present disclosure. Although the present disclosure has been described in detail with reference to the foregoing embodiments, those of ordinary skill in the art should understand that they can still modify the technical solutions described in the foregoing embodiments, or make equivalent substitutions on some or all technical features therein. The modifications or substitutions do not make the essence of the corresponding technical solutions deviate from the spirit and scope of the technical solutions of the embodiments of the present disclosure.

1. A test structure of an integrated circuit, comprising:
a first N-type heavily doped region, a first P-type heavily doped region, and a second N-type heavily doped region located between the first N-type heavily doped region and the first P-type heavily doped region;
wherein the first N-type heavily doped region, the second N-type heavily doped region, and the first P-type heavily doped region are all located on a P-type substrate; or, the first N-type heavily doped region is located in an N well, the second N-type heavily doped region and the first P-type heavily doped region are both located on a P-type substrate, and the N well is located on the P-type substrate; or, the first N-type heavily doped region is located in a deep N well, the second N-type heavily doped region and the first P-type heavily doped region are both located on a P-type substrate, the deep N well is located in an N well, and the N well is located on the P-type substrate;
there is a first distance between the first N-type heavily doped region and the second N-type heavily doped region, and there is a second distance between the second N-type heavily doped region and the first P-type heavily doped region; and
the test structure is configured to test electrical parameters of the integrated circuit corresponding to the test structure by adjusting at least one of the first distance and the second distance.

2. The test structure of an integrated circuit according to claim 1, wherein the first N-type heavily doped region, the second N-type heavily doped region, and the first P-type heavily doped region are all located on the P-type substrate;
the first N-type heavily doped region, the second N-type heavily doped region, and the first P-type heavily doped region form a parasitic NPN transistor; and the test structure is configured to test latch-up characteristics of the parasitic NPN transistor.

3. The test structure of an integrated circuit according to claim 2, wherein the P-type substrate has a parasitic resistor, and the parasitic resistor has a first terminal connected to the first P-type heavily doped region and a second terminal connected to a base of the parasitic NPN transistor.

4. The test structure of an integrated circuit according to claim 1, wherein the first N-type heavily doped region is located in the N well, the second N-type heavily doped region and the first P-type heavily doped region are both located on the P-type substrate, and the N well is located on the P-type substrate;
the N well, the second N-type heavily doped region, and the first P-type heavily doped region form a parasitic NPN transistor; and the test structure is configured to test latch-up characteristics of the parasitic NPN transistor.

5. The test structure of an integrated circuit according to claim 4, wherein the P-type substrate has a parasitic resistor, and the parasitic resistor has a first terminal connected to the first P-type heavily doped region and a second terminal connected to a base of the parasitic NPN transistor.

6. The test structure of an integrated circuit according to claim 1, wherein the first N-type heavily doped region is located in the deep N well, the second N-type heavily doped region and the first P-type heavily doped region are both located on the P-type substrate, the deep N well is located in the N well, and the N well is located on the P-type substrate;
the deep N well, the second N-type heavily doped region, and the first P-type heavily doped region form a parasitic NPN transistor; and the test structure is configured to test latch-up characteristics of the parasitic NPN transistor.

7. The test structure of an integrated circuit according to claim 6, wherein the P-type substrate has a parasitic resistor, and the parasitic resistor has a first terminal connected to the first P-type heavily doped region and a second terminal connected to a base of the parasitic NPN transistor.

8. A test structure of an integrated circuit, comprising:
a first N-type heavily doped region, a first P-type heavily doped region, and a second N-type heavily doped region located between the first N-type heavily doped region and the first P-type heavily doped region;
wherein the second N-type heavily doped region is located in an N well, the first N-type heavily doped region and the first P-type heavily doped region are both located on a P-type substrate, and the N well is located on the P-type substrate; or, the second N-type heavily doped region is located in a deep N well , the first N-type heavily doped region and the first P-type heavily doped region are both located on a P-type substrate, the deep N well is located in an N well, and the N well is located on the P-type substrate; or, the first N-type heavily doped region is located in a first N well, the second N-type heavily doped region is located in a second N well, and the first P-type heavily doped region, the first N well, and the second N well are all located on a P-type substrate;
there is a first distance between the first N-type heavily doped region and the second N-type heavily doped region, and there is a second distance between the second N-type heavily doped region and the first P-type heavily doped region; and
the test structure is configured to test electrical parameters of the integrated circuit corresponding to the test structure by adjusting at least one of the first distance and the second distance.

9. The test structure of an integrated circuit according to claim 8, wherein the second N-type heavily doped region is located in the N well, the first N-type heavily doped region and the first P-type heavily doped region are both located on the P-type substrate, and the N well is located on the P-type substrate;
the N well, the first N-type heavily doped region, and the first P-type heavily doped region form a parasitic NPN transistor; and the test structure is configured to test latch-up characteristics of the parasitic NPN transistor.

10. The test structure of an integrated circuit according to claim 9, wherein the P-type substrate has a parasitic resistor, and the parasitic resistor has a first terminal connected to the first P-type heavily doped region and a second terminal connected to a base of the parasitic NPN transistor.

11. The test structure of an integrated circuit according to claim 8, wherein the second N-type heavily doped region is located in the deep N well, the first N-type heavily doped region and the first P-type heavily doped region are both located on the P-type substrate, the deep N well is located in the N well, and the N well is located on the P-type substrate;
the deep N well, the first N-type heavily doped region, and the first P-type heavily doped region form a parasitic NPN transistor; and the test structure is configured to test latch-up characteristics of the parasitic NPN transistor.

12. The test structure of an integrated circuit according to claim 11, wherein the P-type substrate has a parasitic resistor, and the parasitic resistor has a first terminal connected to the first P-type heavily doped region and a second terminal connected to a base of the parasitic NPN transistor.

13. The test structure of an integrated circuit according to claim 8, wherein the first N-type heavily doped region is located in the first N well, the second N-type heavily doped region is located in the second N well, and the first P-type heavily doped region, the first N well, and the second N well are all located on the P-type substrate;
the first N well, the second N well, and the first P-type heavily doped region form a parasitic NPN transistor; and the test structure is configured to test latch-up characteristics of the parasitic NPN transistor.

14. The test structure of an integrated circuit according to claim 13, wherein the P-type substrate has a parasitic resistor, and the parasitic resistor has a first terminal connected to the first P-type heavily doped region and a second terminal connected to a base of the parasitic NPN transistor.

15. A test structure of an integrated circuit, comprising:
a first N-type heavily doped region, a first P-type heavily doped region, and a second N-type heavily doped region located between the first N-type heavily doped region and the first P-type heavily doped region;
wherein the first N-type heavily doped region is located in a first N well, the second N-type heavily doped region is located in a deep N well, the first P-type heavily doped region is located on a P-type substrate, the first N well is located on the P-type substrate, the deep N well is located in a second N well, and the second N well is located on the P-type substrate; or, the second N-type heavily doped region is located in a first N well, the first N-type heavily doped region is located in a deep N well, the first P-type heavily doped region is located on a P-type substrate, the first N well is located on the P-type substrate, the deep N well is located in a second N well, and the second N well is located on the P-type substrate; or, the first N-type heavily doped region is located in a first deep N well, the second N-type heavily doped region is located in a second deep N well, the first P-type heavily doped region is located on a P-type substrate, the first deep N well is located in a first N well, the second deep N well is located in a second N well, and the first N well and the second N well are located on the P-type substrate;
there is a first distance between the first N-type heavily doped region and the second N-type heavily doped region, and there is a second distance between the second N-type heavily doped region and the first P-type heavily doped region; and
the test structure is configured to test electrical parameters of the integrated circuit corresponding to the test structure by adjusting at least one of the first distance and the second distance.

16. The test structure of an integrated circuit according to claim 15, wherein the first N-type heavily doped region is located in the first N well, the second N-type heavily doped region is located in the deep N well, the first P-type heavily doped region is located on the P-type substrate, the first N well is located on the P-type substrate, the deep N well is located in the second N well, and the second N well is located on the P-type substrate;
the first N well, the deep N well, and the first P-type heavily doped region form a parasitic NPN transistor; and the test structure is configured to test latch-up characteristics of the parasitic NPN transistor.

17. The test structure of an integrated circuit according to claim 16, wherein the P-type substrate has a parasitic resistor, and the parasitic resistor has a first terminal connected to the first P-type heavily doped region and a second terminal connected to a base of the parasitic NPN transistor.

18. The test structure of an integrated circuit according to claim 15, wherein the second N-type heavily doped region is located in the first N well, the first N-type heavily doped region is located in the deep N well, the first P-type heavily doped region is located on a P-type substrate, the first N well is located on the P-type substrate, the deep N well is located in the second N well, and the second N well is located on the P-type substrate;
the first N well, the deep N well, and the first P-type heavily doped region form a parasitic NPN transistor; and the test structure is configured to test latch-up characteristics of the parasitic NPN transistor.

19. The test structure of an integrated circuit according to claim 18, wherein the P-type substrate has a parasitic resistor, and the parasitic resistor has a first terminal connected to the first P-type heavily doped region and a second terminal connected to a base of the parasitic NPN transistor.

20. The test structure of an integrated circuit according to claim 15, wherein the first N-type heavily doped region is located in the first deep N well, the second N-type heavily doped region is located in the second deep N well, the first P-type heavily doped region is located on the P-type substrate, the first deep N well is located in the first N well, the second deep N well is located in the second N well, and the first N well and the second N well are located on the P-type substrate;
the first deep N well, the second deep N well, and the first P-type heavily doped region form a parasitic NPN transistor; and the test structure is configured to test latch-up characteristics of the parasitic NPN transistor;
the P-type substrate has a parasitic resistor, and the parasitic resistor has a first terminal connected to the first P-type heavily doped region and a second terminal connected to a base of the parasitic NPN transistor.
